(19) United States
(12) Patent Application Publication
(10) Pub. No.: US 2013/0146834 A1
(43) Pub. Date: Jun. 13, 2013

(54) QUANTUM DOT-MATRIX THIN FILM AND METHOD OF PRODUCING THE SAME

(71) Applicants: Kyung-sang CHO, Gwacheon-si (KR); Ji-yeon KU, Yongin-si (KR); Byoung-lyong CHOI, Seoul (KR)

(72) Inventors: Kyung-sang CHO, Gwacheon-si (KR); Ji-yeon KU, Yongin-si (KR); Byoung-lyong CHOI, Seoul (KR)

(73) Assignee: SAMSUNG ELECTRONICS CO., LTD., Suwon-si (KR)

(21) Appl. No.: 13/594,141

(22) Filed: Aug. 24, 2012

(30) Foreign Application Priority Data
Dec. 13, 2011 (KR) 10-2011-0134001

(51) Int. Cl. H01L 29/02; H01L 21/20

(52) U.S. Cl. 257/9; 438/478; 257/E29.002; 257/E21.09

(57) ABSTRACT

A quantum dot-matrix thin film and a method of preparing a quantum dot-matrix thin film are provided. The thin film includes quantum dots; an inorganic matrix in which the quantum dots are imbedded; and an interface layer disposed between the quantum dots and the inorganic matrix to surround surfaces of the quantum dots. The method includes preparing a quantum dot solution in which quantum dots with inorganic ligands are dispersed; adding a matrix precursor to the quantum dot solution; coating the quantum dot solution comprising the matrix precursor on a substrate; and annealing the substrate coated with the quantum dot solution.

### CROSS-REFERENCE TO RELATED APPLICATIONS

This application claims priority from Korean Patent Application No. 10-2011-0134001, filed on Dec. 13, 2011, in the Korean Intellectual Property Office, the disclosure of which is incorporated by reference herein in its entirety.

### BACKGROUND

1. Field

The present disclosure relates to a quantum dot-matrix thin film and methods of producing the same.

2. Description of the Related Art

A quantum dot is a semiconductor material having a crystallization structure with a size of several nanometers. The quantum dot demonstrates properties between those of bulk semiconductors of the same material and those of discontinuous molecules. Since the physical, chemical, and electrical properties of a quantum dot may be controlled by changing the size of the material due to quantum confinement effects and large surface to volume ratios, a quantum dot has received great interest for a new property controlling method and material.

Among preparation methods of quantum dots, a wet-chemical synthesis method, which makes colloidal quantum dots, may be used to readily manufacture a mass amount of uniformly nanosized quantum dots with a low-cost process.

### SUMMARY

One or more embodiments provide a quantum dot-matrix thin film with physical, chemical, and electrical properties that are controllable.

One or more embodiments also provide a method of preparing a quantum dot-matrix thin film with physical, chemical, and electrical properties that are controllable.

According to an aspect of an embodiment, there is provided a quantum dot-matrix thin film that includes a plurality of quantum dots; an inorganic matrix in which the plurality of quantum dots are imbedded; and an interface layer disposed between the quantum dots and the inorganic matrix to surround surfaces of the quantum dots.

The quantum dot may include CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, CdHgZnTe, CdZnSeS, CdZnSeTe, CdZnSTe, CdHgSeS, CdHgSeTe, CdHgSTe, HgZnSeS, HgZnSeTe, HgZnSTe; GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb; SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe; Si, Ge, SiC, SiGe, or any combination of at least two thereof.

The inorganic matrix may include a metal chalcogenide complex (MCC).

The interface layer may include an MCC.

A material used to form the interface layer and a material used to form the matrix may be different from each other.

According to an aspect of another embodiment, there is provided a method of preparing a quantum dot-matrix thin film that includes preparing a quantum dot solution in which quantum dots with inorganic ligands are dispersed; adding a matrix precursor to the quantum dot solution; coating the quantum dot solution including the matrix precursor on a substrate; and annealing the substrate coated with the quantum dot solution.

The inorganic ligands may include an MCC.

The matrix precursor may include an MCC.

The inorganic ligand and the matrix precursor may be a same material.

The inorganic ligand and the matrix precursor may be different materials.

A porosity of the quantum dot-matrix thin film and an interval between the quantum dots may be controlled by adjusting an amount of the matrix precursor added to the quantum dot solution.

### BRIEF DESCRIPTION OF THE DRAWINGS

These and/or other aspects will become apparent and more readily appreciated from the following description of embodiments, taken in conjunction with the accompanying drawings in which:

FIG. 1 is a schematic diagram for describing a method of preparing a quantum dot-matrix thin film, according to an embodiment;

FIG. 2 is a flowchart for describing a method of preparing a quantum dot-matrix thin film, according to an embodiment;

FIGS. 3A to 3C illustrate the degree of porosity of the quantum dot-matrix thin film and an interval between quantum dots according to a concentration of a matrix precursor;

FIG. 4 is a schematic cross-sectional view of a quantum dot-matrix film according to an embodiment;

FIG. 5 is a schematic cross-sectional view of a quantum dot-matrix film according to another embodiment;

FIG. 6 illustrates hexagonal close packing and triangular orthobicupola unit cells;

FIG. 7 is a graph illustrating time-resolved photoluminescence of thin films prepared according to Examples 1 to 3 and Comparative Example 1;

FIG. 8 is a graph illustrating time-resolved photoluminescence of quantum dot solutions prepared according to Reference Examples 1 and 2;

FIG. 9 is a graph illustrating time-resolved photoluminescence of quantum dot solutions prepared in Reference Examples 3 and 4;

FIG. 10 is a graph illustrating time-resolved photoluminescence of quantum dot solutions prepared in Examples 4 and 5 and Comparative Examples 1 and 2; and

FIG. 11 shows diagrams schematically illustrating energy levels of structures of thin films prepared in Examples 4 and 5 and Comparative Examples 1 and 2.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present inventive concept. Expressions such as “at least one of,” when preceding a list of elements, modify the entire list of elements and do not modify the individual elements of the list.

Attempts to apply quantum dots to electronic devices such as a quantum dot light-emitting diode (QD LED), a QD solar cell, and a QD transistor have been continuously made but actual industrial application is difficult. One of the reasons is because, though the quantum dot itself is made of a semiconductor material, organic ligands coated on a surface of the quantum dot act as an insulating barrier layer, so that an electric conductivity of the quantum dot is reduced. Research into improving electrical conductivity of quantum dots by replacing organic ligands of the quantum dots with inorganic ligands has been conducted. However, there is a need to develop a method of preparing a thin film with physical, chemical, and electrical properties that are controllable by using quantum dots with inorganic ligands for practical use in devices. Exemplary embodiments provided herein are directed to such a method.

Terms used herein are defined as follows.

Quantum dots as used herein are an elemental semiconductor of a compound semiconductor composed of particles of a nanometer to several tens of nanometers in size. A quantum dot may have a core-shell structure, and each of a core and a shell may be formed of one or more layers. For example, the quantum dot may have a core-shell-shell structure.

Organic ligands are organic compounds that passivate or are coordinately bonded to the surface of quantum dots, and inorganic ligands are inorganic compounds that passivate or are coordinately bonded to the surface of quantum dots.

A matrix is an element constituting a thin film in which quantum dots are distributed.

A matrix precursor is a pre-material forming a matrix when a thin film is formed.

A quantum dot-matrix precursor solution is a solution in which quantum dots and a matrix precursor are dissolved or distributed.

A quantum dot-matrix thin film is a thin film in which quantum dots are imbedded in a matrix, or a thin film in which a matrix is partially or fully packed between quantum dots. In a quantum dot-matrix thin film, an interface layer may be formed between quantum dots and a matrix.

Hereinafter, a method of preparing a quantum dot-matrix thin film, according to an embodiment, is described in detail.

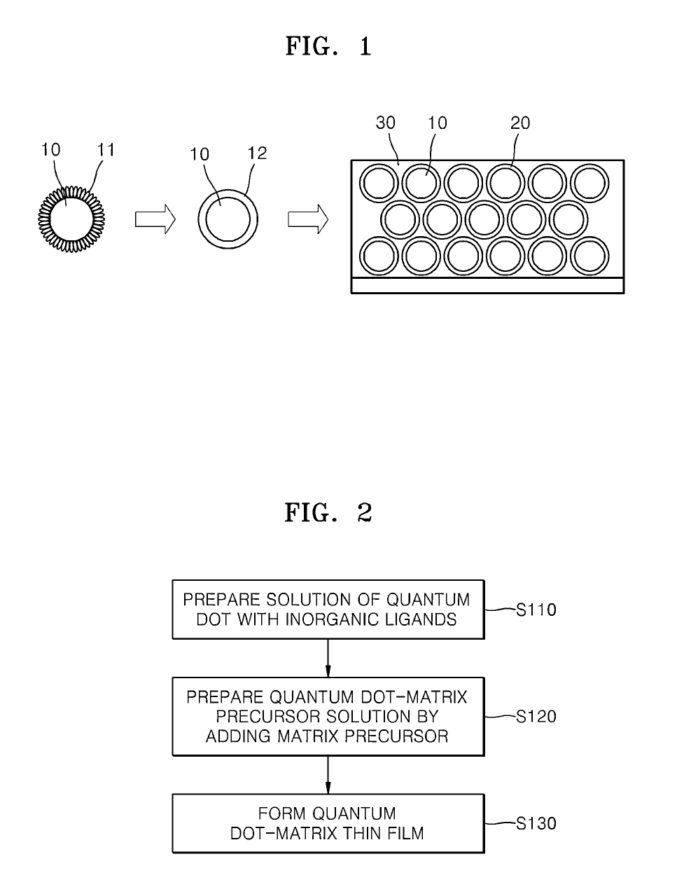

FIG. 1 is a schematic diagram for describing a method of preparing a quantum dot-matrix thin film, according to an embodiment. Referring to FIG. 1, a quantum dot 10 with inorganic ligands 12 is prepared by exchanging organic ligands 11 of the quantum dot 10 with inorganic ligands 12. Then, a quantum dot-matrix thin film including the quantum dot 10, an interface layer 20, and a matrix 30 is prepared by using the quantum dot 10 with inorganic ligands 12. In this regard, if the inorganic ligand 12 and the matrix 30 are the same material, it is possible to form the thin film without forming the interface layer 20.

FIG. 2 is a flowchart for describing a method of preparing a quantum dot-matrix thin film, according to an embodiment.

Referring to FIG. 2, a solution of a quantum dot with inorganic ligands is prepared (S110). The solution of a quantum dot with inorganic ligands is a solution in which quantum dots with inorganic ligands are dissolved or dispersed in a solvent.

For example, the quantum dot with inorganic ligands may be prepared by exchanging organic ligands of the quantum dot with inorganic ligands. For example, the exchange of ligands may be done via phase transfer of the quantum dots by mixing a solution of quantum dots with organic ligands with a solution of inorganic ligands. In this regard, the solution of quantum dots with inorganic ligands may include an inorganic solvent or an organic solvent, and the solution of quantum dots with organic ligands may include a non-polar organic solvent or a polar organic solvent. Optionally, a process of exchanging the organic ligands of the quantum dot with second organic ligands may further be performed before the exchange with the inorganic ligands.

A quantum dot may be formed of, for example, a Group II-VI semiconductor compound, a Group III-V semiconductor compound, a Group IV-VI semiconductor compound, a Group IV element or compound, or any combination thereof. The Group II-VI semiconductor compound may include a binary compound such as CdS, CdSe, CdTe, ZnS, ZnSe, ZnTe, ZnO, HgS, HgSe, HgTe, or a combination thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, or a combination thereof; and a quaternary compound such as CdHgZnTe, CdZnSeS, CdZnSeTe, CdZnSTe, CdHgSeS, CdHgSeTe, CdHgSTe, HgZnSeS, HgZnSeTe, HgZnSTe, or a combination thereof. The Group III-V semiconductor compound may include a binary compound such as GaN, GaP, GaAs, GaSb, AlN, AlP, AlAs, AlSb, InN, InP, InAs, InSb, or a combination thereof; a ternary compound such as GaNP, GaNAs, GaNSb, GaPAs, GaPSb, AlNP, AlNAs, AlNSb, AlPAs, AlPSb, InNP, InNAs, InNSb, InPAs, InPSb, GaAlNP, or a combination thereof; or a quaternary compound such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or a combination thereof. The Group IV-VI semiconductor compound may include a binary compound such as SnS, SnSe, SnTe, PbS, PbSe, PbTe, or a combination thereof; a ternary compound such as SnSeS, SnSeTe, SnSTe, PbSeS, PbSeTe, PbSTe, SnPbS, SnPbSe, SnPbTe, or a combination thereof; or a quaternary compound such as SnPbSSe, SnPbSeTe, SnPbSTe, or a combination thereof. The Group IV element or compound may be Si, Ge, SiC, SiGe, or any combination thereof. For example, the quantum dot may be formed of CdSe/CdS/ZnS.

Examples of the organic ligand may include, trioctylphosphine (TOP), trioctylphosphine oxide (TOPO), oleic acid, oleylamine, octylamine, trioctyl amine, hexadecylamine, octanethiol, dodecanethiol, hexylphosphonic acid (HPA), tetradecylphosphonic acid (TDPA), octylphosphonic acid (OPA), and any mixture thereof, but are not limited thereto.

The second organic ligand may be a material with a polarity such as mercapto propionic acid (MPA), cysteamine, or mercapto acetic acid.

The inorganic ligand may be metal chalcogenide complexes (MCC), but is not limited thereto. The MCC may include Sn2S6, Sn2Se6, In2Se4, In2Te3, Ga2Se3, CuInSe2, Cu7S4, Hg3Se4, Sb2Te3, ZnTe, or a hydrazine hydrate thereof. The hydrazine hydrate may be hydrazine monohydrate, hydrazine dihydrate, hydrazine trihydrate, hydrazine tetrahydrate, hydrazine pentahydrate, hydrazine hexahydrate, or any mixture thereof.

A quantum dot-matrix precursor solution is prepared by adding a matrix precursor to the solution of a quantum dot with inorganic ligands (S120). The matrix precursor may be MCC as the inorganic ligand. The MCC may include Sn2S6, Sn2Se6, In2Se4, In2Te3, Ga2Se3, CuInSe2, Cu7S4, Hg3Se4, Sb2Te3, ZnTe, or a hydrazine hydrate thereof. The hydrazine hydrate may be hydrazine monohydrate, hydrazine dihydrate, hydrazine trihydrate, hydrazine tetrahydrate, hydrazine pentahydrate, hydrazine hexahydrate, or any mixture thereof. The matrix precursor and the inorganic ligand of the quantum dot may be the same as or different from each other.

If the matrix precursor and the inorganic ligand of the quantum dot are same, the inorganic ligand of the quantum dot is not distinguished from the matrix in the thin film, so that the thin film may have a quantum dot/matrix structure in which the quantum dots are imbedded in the matrix. On the other hand, if the matrix precursor and the inorganic ligand of the quantum dot are different from each other, the thin film may have a quantum dot/interface layer/matrix structure in which the interface layer is disposed between the quantum dot and the matrix.

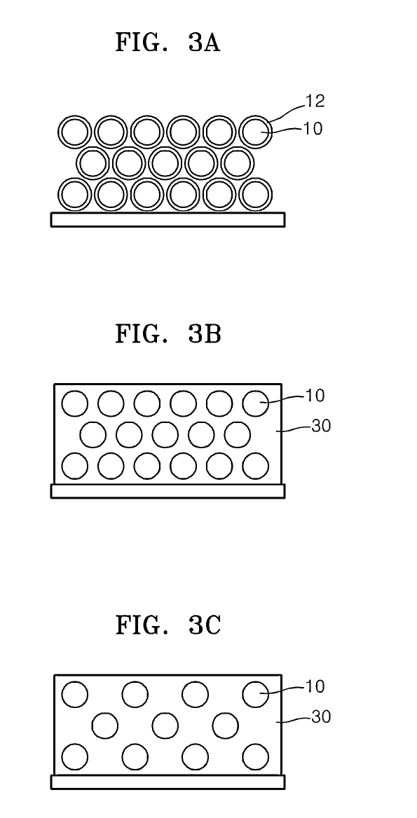

The degree of passivation in the surface of the quantum dot in the quantum dot-matrix thin film, the degree of porosity of the thin film, and the interval between the quantum dots may be controlled by adjusting the concentration of the matrix precursor in the quantum dot-matrix precursor solution. FIGS. 3A to 3C illustrate the degree of porosity of the quantum dot-matrix thin film and the interval between quantum dots according to the concentration of the matrix precursor. Referring to FIG. 3A, the quantum dot-matrix thin film may become porous since gaps between quantum dots are not completely filled with the matrix when the concentration of the matrix precursor is not sufficient. However, as the concentration of the matrix precursor increases, the gaps between the quantum dots may be completely filled with the matrix in the thin film, as shown in FIG. 3B. If the concentration of the matrix precursor exceeds a threshold level at which the thin film becomes non-porous, a density of the quantum dots decreases in the thin film, so that the interval between the quantum dots may increase, as shown in FIG. 3C.

Referring to FIG. 2, a quantum dot-matrix thin film is formed by using the quantum dot-matrix precursor solution (S130). For example, the quantum dot-matrix thin film may be formed by coating the quantum dot-matrix precursor solution on a substrate and annealing the coating. The quantum dot-matrix precursor solution may be coated on the substrate by spin coating or the like. After coating the solution, the inorganic ligands of the quantum dots and the matrix precursor are converted into an interface layer or a matrix by the annealing to form the thin film with the quantum dots. For example, the hydrazine hydrate is removed by the annealing, and Sn2S6 or Sn2Se6 may be converted into SnS2 or SnSe2.

If the matrix precursor and the inorganic ligands of the quantum dot are different from each other, ligand exchanges may occur between the inorganic ligands of the quantum dot and the matrix precursor. In order to prevent the ligand exchanges, the thin film may be formed right after adding the matrix precursor to the quantum dot solution.

In a method of preparing the quantum dot-matrix thin film, according to the current exemplary embodiment, the degree of porosity of the quantum dot-matrix thin film and the interval between the quantum dots may be controlled by adjusting the amount of the matrix precursor added to the solution of a quantum dot with inorganic ligands. Properties of the quantum dot-matrix thin film may be controlled by adjusting not only the size of the quantum dot but also the porosity of the quantum dot-matrix thin film and the interval between the quantum dots, and thus, the quantum dot-matrix thin film may be applied to various thin films and devices.

In addition, the quantum dot-matrix thin film may have a quantum dot/matrix structure or a quantum dot/interface layer/matrix structure by selecting a material that is the same as or different from the inorganic ligand of the quantum dot, as the matrix precursor material. The quantum dot-matrix thin film having the quantum dot/interface layer/matrix structure may have various properties such as charge transfer, energy transfer, and energy storing by combining a material for the interface layer and a material for the matrix in various ways. Such various properties may be obtained by controlling an energy band level by combining the material for the interface layer and the material for the matrix in various ways.

Furthermore, the quantum dot-matrix thin film may have excellent charge transfer properties by using the quantum dot in which the organic ligands that may function as an insulating barrier are replaced with the inorganic ligands.

Hereinafter, a quantum dot-matrix thin film according to an exemplary embodiment is described in detail.

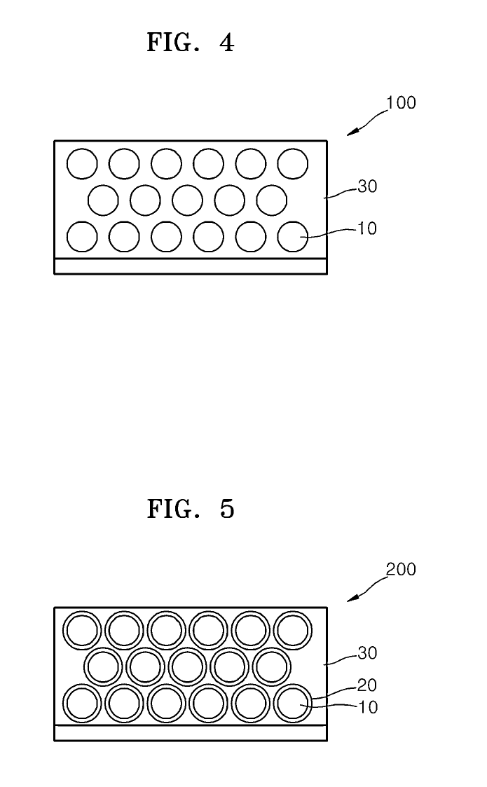

FIG. 4 is a schematic cross-sectional view of a quantum dot-matrix film according to an embodiment. Referring to FIG. 4, a quantum dot-matrix thin film 100 includes quantum dots 10 and a matrix 30 in which the precursor quantum dots 10 are distributed.

The quantum dot 10 may be formed of, for example, a Group II-VI semiconductor compound, a Group III-V semiconductor compound, a Group IV-VI semiconductor compound, a Group IV element or compound, or any combination thereof. The Group II-VI semiconductor compound may include a binary compound such as CdS, CdSe, CdTe, ZnS, ZnSe, ZnTe, ZnO, HgS, HgSe, HgTe, or a combination thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, or a combination thereof; and a quaternary compound such as CdHgZnTe, CdZnSeS, CdZnSeTe, CdZnSTe, CdHgSeS, CdHgSeTe, CdHgSTe, HgZnSeS, HgZnSeTe, HgZnSTe, or a combination thereof. The Group III-V semiconductor compound may include a binary compound such as GaN, GaP, GaAs, GaSb, AlN, AlP, AlAs, AlSb, InN, InP, InAs, InSb, or a combination thereof; a ternary compound such as GaNP, GaNAs, GaNSb, GaPAs, GaPSb, AlNP, AlNAs, AlNSb, AlPAs, AlPSb, InNP, InNAs, InNSb, InPAs, InPSb, GaAlNP, or a combination thereof; or a quaternary compound such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or a combination thereof. The Group IV-VI semiconductor compound may include a binary compound such as SnS, SnSe, SnTe, PbS, PbSe, PbTe, or a combination thereof; a ternary compound such as SnSeS, SnSeTe, SnSTe, PbSeS, PbSeTe, PbSTe, SnPbS, SnPbSe, SnPbTe, or a combination thereof; or a quaternary compound such as SnPbSSe, SnPbSeTe, SnPbSTe, or a combination thereof. The Group IV element or compound may be Si, Ge, SiC, SiGe, or any combination thereof. For example, the quantum dot may be formed of CdSe/CdS/ZnS.

The matrix 30 may be formed of an inorganic material. The matrix 30 may be formed of, for example, an MCC, but is not limited thereto. Examples of the MCC constituting the matrix 30 may include Sn2S6, Sn2Se6, In2Se4, In2Te3, Ga2Se3, CuInSe2, Cu7S4, Hg3Se4, Sb2Te3, or ZnTe.

Physical, chemical, and electrical properties of the quantum dot-matrix thin film 100 may vary according to a material used to form the quantum dot 10, the size of the quantum dot 10, and a material used to form the matrix 30. Physical and electrical properties of the quantum dot-matrix thin film 100 may vary according to the interval between the quantum dots 10 and the porosity of the quantum dot-matrix thin film 100.

FIG. 5 is a schematic cross-sectional view of a quantum dot-matrix film according to another exemplary embodiment. Referring to FIG. 5, a quantum dot-matrix thin film 200 includes quantum dots 10, a matrix 30 in which the quantum dots 10 are distributed, and an interface layer 20 disposed between the quantum dots 10 and the matrix 30. The interface layer 20 surrounds the surface of the quantum dots 10 to be in contact with both of the quantum dots 10 and the matrix 30.

The materials used to form the quantum dots 10 and the matrix 30 are described above with reference to the quantum dot-matrix thin film 100 shown in FIG. 4. The interface layer 20 and the matrix 30 of FIG. 5 are formed of different materials. However, a material used to form the interface layer 20 may also be MCC, as that of the matrix 30, but is not limited thereto. Examples of the MCC constituting the interface layer 20 may include Sn2S6, Sn2Se6, In2Se4, In2Te3, Ga2Se3, CuInSe2, Cu7S4, Hg3Se4, Sb2Te3, or ZnTe.

The quantum dot-matrix thin film 200 may have various properties such as charge transfer, energy transfer, and energy storing by combining a material for the interface layer 20 and a material for the matrix 30 in various ways.

### Example 1

### (1) Preparation of Solution of Quantum Dot with Inorganic Ligands

(a-1) Preparation of Sn2S6 Hydrazine Monohydrate Solution

Powdered sulfur (S) was dissolved in a hydrazine monohydrate (N2H4.H2O) solution to prepare a 1 M sulfur hydrazine monohydrate solution. The hydrazine monohydrate solution and powdered tin (Sn) were added to the 1 M sulfur hydrazine monohydrate solution, and reacted. The reaction took place at room temperature while stirring for about an hour. Remaining precipitates were removed from the reaction solution after the reaction by centrifuging to prepare an Sn2S6 hydrazine monohydrate solution. The Sn2S6 hydrazine monohydrate solution includes Sn2S6 hydrazine monohydrate in which Sn2S6 and hydrazine monohydrate are bonded to each other.

(a-2) Preparation of Sn2S6 Hydrazine Monohydrate Ethanolamine Solution

The Sn2S6 hydrazine monohydrate solution was dried using N2 gas to remove the hydrazine monohydrate solution and leave the Sn2S6 hydrazine monohydrate only. The separated Sn2S6 hydrazine monohydrate was dissolved in an ethanolamine solution to prepare a Sn2S6 hydrazine monohydrate ethanolamine solution.

(b) Preparation of CdSe/CdS/ZnS Quantum Dot-Cyclohexane Solution

CdSe/CdS/ZnS quantum dots were dispersed or dissolved in a cyclohexane solution to prepare a CdSe/CdS/ZnS quantum dot-cyclohexane solution (refer to Advanced materials, 2007, vol. 19, pages 1927-1932). The CdSe/CdS/ZnS quantum dot has a core-shell structure of CdSe/CdS/ZnS in this order from inside to outside. In addition, a mixed organic ligands of oleic acid, trioctylphosphine (TOP), trioctylphosphine oxide (TOPO), or trioctylamine is coordinately bonded with the surface of the CdSe/CdS/ZnS quantum dots.

(c) Preparation of Solution of a CdSe/CdS/ZnS Quantum Dot with Sn2S6 Hydrazine Monohydrate Ligands

The Sn2S6 hydrazine monohydrate ethanolamine solution prepared in operation (a-2) was added to the CdSe/CdS/ZnS quantum dot-cyclohexane solution prepared in operation (b), and a ligand exchange reaction was performed while stirring the mixture for 8 hours at room temperature. By the ligand exchange reaction, the mixed organic ligands of the CdSe/CdS/ZnS quantum dots were exchanged with the Sn2S6 hydrazine monohydrate ligands. As a result of the ligand exchange reaction, a solution of a CdSe/CdS/ZnS quantum dot with Sn2S6 hydrazine monohydrate ligands was prepared.

### (2) Preparation of Quantum Dot-Matrix Precursor Solution

Powdered Sn2S6 was added to the solution of the CdSe/CdS/ZnS quantum dot with Sn2S6 hydrazine monohydrate ligands prepared in operation (c) such that the mass ratio of the quantum dot with Sn2S6 hydrazine monohydrate ligands to Sn2S6 was 1:0.3. The solution to which the powdered Sn2S6 was added was mixed.

### (3) Formation of Quantum Dot-Matrix Thin Film

The solution of the CdSe/CdS/ZnS quantum dot with Sn2S6 hydrazine monohydrate ligands to which powdered Sn2S6 was added was spin coated and annealed at 200° C. for 20 minutes to form a CdSe/CdS/ZnS quantum dot-Sn2S2 matrix thin film with a thickness of 30 nm.

### Example 2

A CdSe/CdS/ZnS quantum dot-Sn2S2 matrix thin film was formed in the same manner as in Example 1, except that the powdered Sn2S6 was added to the solution of the CdSe/CdS/ZnS quantum dot with Sn2S6 hydrazine monohydrate ligands such that the mass ratio of the quantum dot with Sn2S6 hydrazine monohydrate ligands to Sn2S6 was 1:1 instead of 1:0.3.

### Example 3

A CdSe/CdS/ZnS quantum dot-Sn2S2 matrix thin film was formed in the same manner as in Example 1, except that the powdered Sn2S6 was added to the solution of the CdSe/CdS/ZnS quantum dot with Sn2S6 hydrazine monohydrate ligands such that the mass ratio of the quantum dot with Sn2S6 hydrazine monohydrate ligands to Sn2S6 was 1:3 instead of 1:0.3.

### Comparative Example 1

A CdSe/CdS/ZnS quantum dot/Sn2S2 thin film was formed in the same manner as in Example 1, except that only the solution of the CdSe/CdS/ZnS quantum dot with Sn2S6 hydrazine monohydrate ligands was used without adding powdered Sn2S6 thereto. The CdSe/CdS/ZnS quantum dot/Sn2S2 thin film is a thin film in which the surface of the CdSe/CdS/ZnS quantum dot is surrounded with an Sn2S2 layer.

Interval Between Quantum Dots in Quantum Dot-Matrix Thin Film

A unit cell structure of the CdSe/CdS/ZnS quantum dot in the quantum dot-matrix thin film was assumed to have a hexagonal packing and triangular orthobicupola structure. The alignment of the CdSe/CdS/ZnS quantum dots in the quantum dot-matrix thin film was modeled by assuming a diameter (2r) of the quantum dot was 6.8 nm. Then, molar ratios of Zn:Sn of the thin films prepared according to Examples 1 to 3 and Comparative Example 1 were measured by using X-ray photoelectron spectroscopy (XPS). Measured by using the XPS, Zn originated from the CdSe/CdS/ZnS quantum dot, and Sn originated from the Sn2S2 matrix.

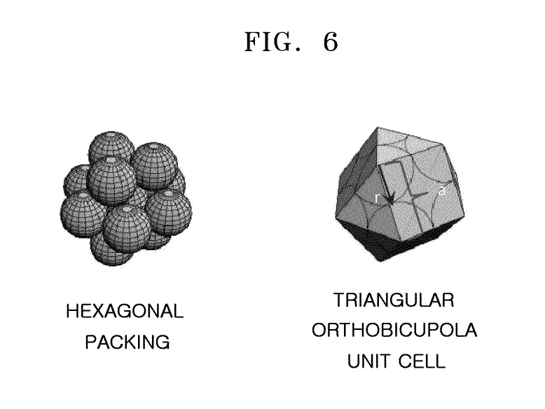

FIG. 6 illustrates hexagonal packing and triangular orthobicupola unit cells. In the hexagonal packing and triangular orthobicupola unit cells, a packing density of the quantum dot is represented by Equation 1 below, and a packing density of the matrix is represented by Equation 2 below.

$$\begin{matrix}{η}_{QD} = \frac{8 π {r}^{3}}{3 \sqrt{2} {a}^{3}} & ( 1 ) \\ {η}_{matrix} = 1 - \frac{8 π {r}^{3}}{3 \sqrt{2} {a}^{3}} & ( 2 )\end{matrix}$$

In the thin films of Examples 1 to 3 and Comparative Example 1, it was assumed that the quantum dots are aligned in the hexagonal packing structure throughout the thin film. Thus, the increase in the interval between the quantum dots leads to the increase in the diameter of the quantum dots in the hexagonal close packing structure.

The mass ratio of Zn:Sn was calculated based on the molar ratio of Zn:Sn measured by using the XPS in consideration of molecular weights thereof, and the mass ratio was divided by a density of the quantum dot and the matrix to obtain a volume ratio of quantum dot:matrix. Then, the packing density (η) of the quantum dot was obtained based on the volume ratio, and a virtual diameter of the quantum dot, i.e., a distance between centers of two quantum dots, was obtained from the packing density (η) of the quantum dot by using Equations 1 and 2. The distance between the centers of two quantum dots (a) denotes a distance between centers of adjacent quantum dots. The interval between the quantum dots was obtained by subtracting the diameter (6.8 nm) of the quantum dot from the distance between the centers of two quantum dots (a). The interval between the quantum dots is a distance between surfaces of adjacent quantum dots.

The molar ratios of Zn:Sn measured by using the XPS, distances between centers of quantum dots calculated therefrom, and intervals between the quantum dots of the thin films prepared according to Examples 1 to 3 and Comparative Example 1 are listed in Table 1 below.

TABLE 1

| | Quantum | | Distance | |
|---|---|---|---|---|
| | dot:Matrix | Zn:Sn | between | Interval |
| | precursor | (molar | centers of | between |
| | (mass ratio) | ratio) | quantum dots | quantum dots |
| Comparative | 1:0 | 1:0.26 | . | . |
| Example 1 | | | | |
| Example 1 | 1:0.3 | 1:0.51 | . | . |
| Example 2 | 1:1 | 1:1.06 | 6.87 nm | 0.07 nm |
| Example 3 | 1:3 | 1:8.33 | 9.84 nm | 2.04 nm |

Referring to Table 1, since the molar ratios of Zn:Sn of the thin films in Comparative Example 1 and Example 1 were greater than 1, the distances between centers of the quantum dots were not calculated. Thus, it may be identified that the thin films prepared in Comparative Example 1 and Example 1 have a porous structure in which some gaps between the quantum dots are not filled, and the quantum dots are densely aligned, so that the distance between the centers of the quantum dots was 2r=6.8 nm.

This is because the thin film of Comparative Example 1 is formed only of the quantum dot solution, and the amount of the matrix material was insufficient in Example 1. Since the amount of the matrix filling between the quantum dots in the thin film is not sufficient, the thin film has a porous structure.

In Example 2, the distance between centers of the quantum dots was 6.87 nm, and the interval between the quantum dots was 0.07 nm. It was identified that space between the quantum dots is filled with the matrix and the quantum dots are densely formed in the thin film of Example 2 since the interval between the quantum dots is very small.

In Example 3, the distance between the quantum dots was 9.84 nm, and the interval between the quantum dots was 2.04 nm. It was identified that the quantum dots were dispersed in the matrix with an interval since the space between the quantum dots is filled with the matrix in Example 3, and the interval between the quantum dots of Example 3 was greater than that between the quantum dots of Example 2.

Emission Intensity of Sn2S6 Quantum Dot-Matrix Thin Film

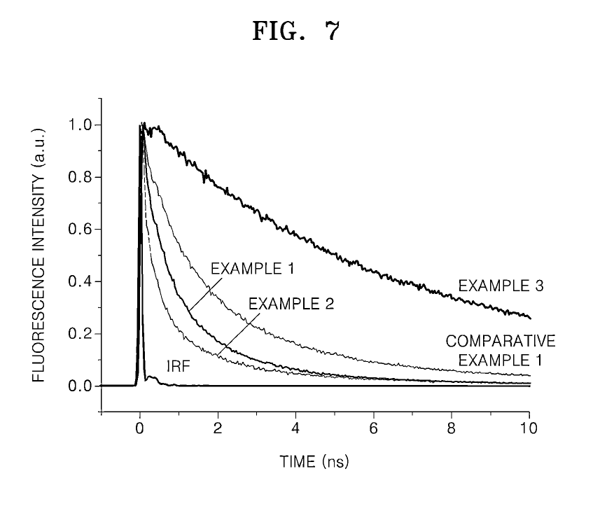

FIG. 7 is a graph illustrating time-resolved photoluminescence of the thin films prepared according to Examples 1 to 3 and Comparative Example 1. A pulsed laser beam having a wavelength of 400 nm was irradiated to measure fluorescence at 610 nm. The instrument response function (IRF) was 50 ps.

Referring to FIG. 7, an emission lifetime of the thin films decreases in the order of Comparative Example 1, Example 1, and Example 2. This tendency of the emission lifetime decreasing in the order of Comparative Example 1, Example 1, and Example 2 corresponds to a tendency of the degree of porosity decreasing from the porous structure including gaps between the quantum dots to the non-porous structure in which the gaps between the quantum dots are filled with the matrix as the amount of the matrix increases in the thin film.

This is because a charge transport rate from the inside of the quantum dot to the inorganic materials that passivate the surface of the quantum dot increases as the degree of passivation with the matrix material that is an inorganic material increases on the surface of the quantum dots. In the quantum dots, since charge transport and fluorescence compete with each other, as the charge transport rate increases, a decay rate of fluorescence increases, thereby reducing an emission lifetime. The increase in the charge transport rate from the inside of the quantum dot to the surface of the quantum dot is caused by a low energy barrier of the inorganic matrix on the surface of the quantum dot.

On the other hand, the emission lifetime of the thin film rapidly increased in Example 3. This is because energy transfer between the quantum dots through the matrix decreases as the interval between the quantum dots increases when the gaps between the quantum dots are completely filled with the matrix in Example 3.

Based on the result of the emission lifetime shown in FIG. 7, it was identified that the quantum dot-matrix thin film may be controlled to have a porous structure or a non-porous structure by adjusting the volume ratio between the quantum dots and the matrix, and the interval between the quantum dots may be adjusted in the quantum dot-matrix thin film. The charge transport characteristics of the thin film may be controlled by adjusting the degree of porosity of the quantum dot-matrix thin film and the interval between the quantum dots.

### Reference Example 1

A solution of a CdSe/CdS/ZnS quantum dot with organic ligands was prepared in the same manner as in operation (1)-(b) of Example 1.

### Reference Example 2

A solution of a CdSe/CdS/ZnS quantum dot with Sn2S6 hydrazine monohydrate ligands was prepared in the same manner as in operation (1) of Example 1.

### Reference Example 3

A CdSe/CdS/ZnS quantum dot thin film having a thickness of 30 nm was formed by spin coating the solution prepared in Reference Example 1 on a substrate and annealing the coating at 200° C. for 20 minutes.

### Reference Example 4

A CdSe/CdS/ZnS quantum dot thin film having a thickness of 30 nm was formed by spin coating the solution prepared in Reference Example 2 on a substrate and annealing the coating at 200° C. for 20 minutes.

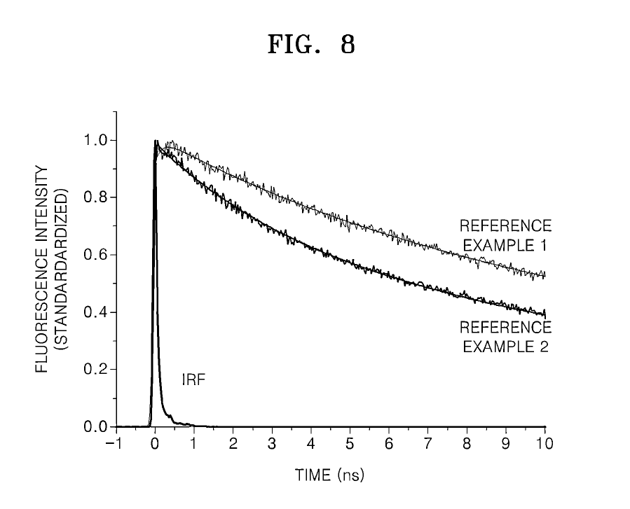

FIG. 8 is a graph illustrating time-resolved photoluminescence of the quantum dot solutions prepared in Reference Examples 1 and 2. A pulsed laser beam having a wavelength of 400 nm was irradiated to measure fluorescence at 590 nm, and each emission spectrum was fitted in order to measure a decay rate of fluorescence. The IRF was 50 ps.

Referring to FIG. 8, the emission lifetime of the solution of a quantum dot with inorganic ligands prepared in Reference Example 2 was shorter than that of the solution of a quantum dot with organic ligands prepared in Reference Example 1. This is because an energy barrier from the quantum dot to the inorganic ligands was lower than that to organic ligands, so that the charge transport from the quantum dot to the ligands of the surface of the quantum dot was faster in the quantum dot solution prepared in Reference Example 2 than in the quantum dot solution prepared in Reference Example 1.

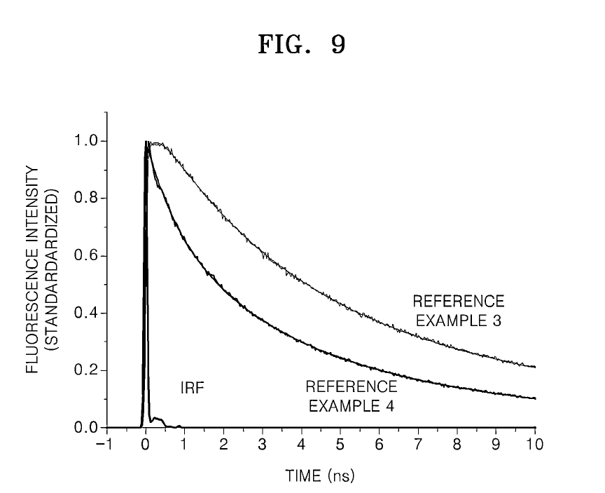

FIG. 9 is a graph illustrating time-resolved photoluminescence of the quantum dot solutions prepared in Reference Examples 3 and 4. A pulsed laser beam having a wavelength of 400 nm was irradiated to measure fluorescence at 600 nm, and each emission spectrum was fitted in order to measure a decay rate of fluorescence. The IRF was 50 ps.

Referring to FIG. 9, the emission lifetime of the thin film of the quantum dot with inorganic ligands prepared in Reference Example 4 was shorter than that of the thin film of the quantum dot with organic ligands prepared in Reference Example 3. This is also because the charge transport from the quantum dot to the ligands of the surface of the quantum dot was faster in the thin film of the quantum dot with inorganic ligands prepared in Reference Example 4 than in the thin film of the quantum dot with organic ligands prepared in Reference Example 3, as shown in the result of Reference Examples 1 and 2. An emission lifetime of the fluorescence spectrum of Reference Examples 3 and 4 of FIG. 9 was shorter than that of the fluorescence spectrum of Reference Examples 1 and 2 of FIG. 8. This is because the distance between the quantum dots in the thin film form of Reference Examples 3 and 4 was shorter than the distance between the quantum dots in the solution form of Reference Examples 1 and 2 since an energy transfer between the quantum dots is in proportion to the distance between the quantum dots to the 6th power.

### Example 4

A solution of a CdSe/CdS/ZnS quantum dot with Sn2S6 hydrazine monohydrate ligands was prepared in the same manner as in operation (1) of Example 1. Powdered Sn2Se6 was added to the quantum dot solution such that a mass ratio of the quantum dot:Sn2Se6 was 1:5, and then the solution was mixed. The quantum dot solution, including the powdered Sn2Se6, was spin coated on a substrate and annealed at 200° C. for 20 minutes to form a CdSe/CdS/ZnS quantum dot-SnS2/SnSe2 matrix thin film with a thickness of 30 nm. CdSe/CdS/ZnS quantum dot/SnS2/SnSe2 matrix thin film is a thin film including an SnS2 interface layer between the CdSe/CdS/ZnS quantum dot and the SnSe2 matrix.

### Example 5

A solution of a CdSe/CdS/ZnS quantum dot with Sn2Se6 hydrazine monohydrate ligands was prepared in the same manner as in the preparation of the quantum dot solution of operation (1) of Example 1, except that powdered selenium (Se) was used instead of powdered sulfur (S). Powdered Sn2S6 was added to the quantum dot solution such that a mass ratio of the quantum dot:Sn2S6 was 1:5, and then the solution was mixed. The quantum dot solution, including the powdered Sn2S6, was spin coated on a substrate and annealed at 200° C. for 20 minutes to form a CdSe/CdS/ZnS quantum dot-SnSe2/SnS2 matrix thin film with a thickness of 30 nm. The CdSe/CdS/ZnS quantum dot/SnSe2/SnS2 matrix thin film is a thin film including an SnSe2 interface layer between the CdSe/CdS/ZnS quantum dot and the SnS2 matrix.

### Comparative Example 2

A CdSe/CdS/ZnS quantum dot SnSe2 thin film was prepared in the same manner as in Comparative Example 1, except that powdered selenium (Se) was used instead of powdered sulfur (S). The CdSe/CdS/ZnS quantum dot/SnSe2 thin film is a thin film in which the surface of the CdSe/CdS/ZnS quantum dot is surrounded with the SnSe2 layer.

Fluorescence Intensity of Quantum Dot/Interface Layer/Matrix Thin Film

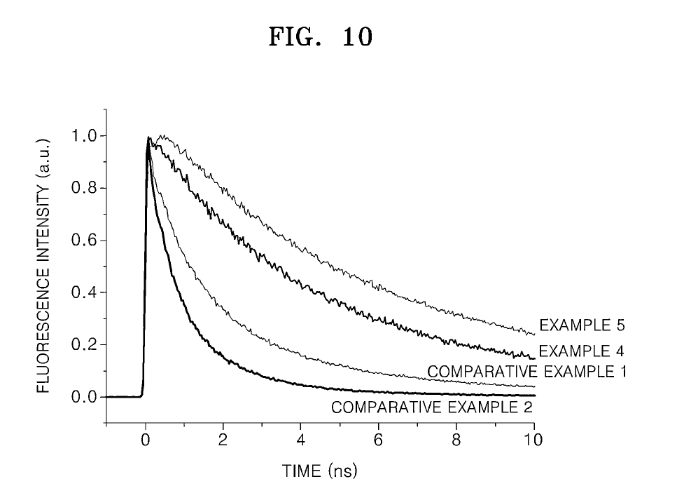

FIG. 10 is a graph illustrating time-resolved photoluminescence of the quantum dot thin films prepared in Examples 4 and 5 and Comparative Examples 1 and 2. A pulsed laser beam having a wavelength of 400 nm was irradiated to measure fluorescence at 610 nm. The thin film prepared in Comparative Example 1 has a quantum dot/SnS2 structure, the thin film prepared in Comparative Example 2 has a quantum dot/SnSe2 structure, the thin film prepared in Example 4 has a quantum dot/SnS2/SnSe2 matrix structure, and the thin film prepared in Example 5 has a quantum dot/SnSe2/SnS2 matrix structure.

Referring to FIG. 10, decay rates decrease in the order of Comparative Example 2, Comparative Example 1, Example 4, and Example 5. That is, an emission lifetime increases in the order of Comparative Example 2, Comparative Example 1, Example 4, and Example 5. The emission lifetime in Examples 4 and 5 was longer than that of Comparative Examples 1 and 2, since the mass ratio of the matrix to the quantum dot in Examples 4 and 5 was greater than that in Comparative Examples 1 and 2, so that the interval between the quantum dots in Examples 4 and 5 was greater than that in Comparative Examples 1 and 2. Thus, the energy transfer between the quantum dots of Examples 4 and 5 was less than that of Comparative Examples 1 and 2.

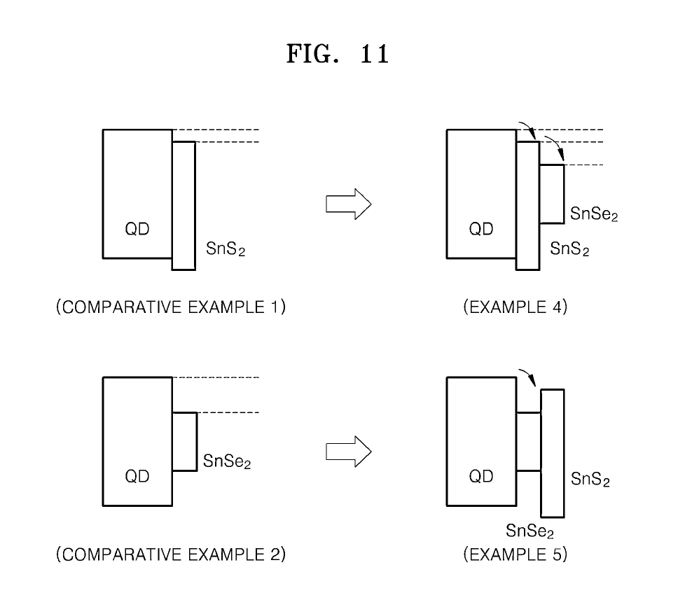

The emission lifetime of the thin film prepared in Comparative Example 2 was shorter than that of Comparative Example 1, and the emission lifetime of the thin film prepared in Example 4 was shorter than that of Example 5, due to the energy level difference between the quantum dot and SnSe2, and between the quantum dot and SnS2. FIG. 11 show diagrams schematically illustrating energy levels of the structures of the thin films prepared according to Examples 4 and 5 and Comparative Examples 1 and 2.

Referring to FIG. 11, an energy level difference of a valance band between the quantum dot and the SnSe2 matrix of the thin film prepared in Comparative Example 2 is greater than an energy level difference of a valance band between the quantum dot and the SnS2 matrix of the thin film prepared in Comparative Example 1. Thus, electron transport from the quantum dot to the matrix is faster than in Comparative Example 2 than in Comparative Example 1, so that an emission lifetime of the quantum dot of Example 2 is shorter than that of the quantum dot of Example 1.

Referring back to FIG. 11, the energy level of a conduction band decreases in the order of the quantum dot, the SnS2 interface layer, and the SnSe2 matrix in Example 4. On the other hand, the energy level of a conduction band is the lowest in the SnSe2 interface layer, and increases in the SnS2 matrix in Example 5, so that an energy barrier exists in a direction from the SnSe2 interface layer to the SnS2 matrix. Electron transport in the thin film prepared in Example 4 in which the energy level of a conduction band is sequentially decreased is faster than that in the thin film prepared in Example 5 in which the energy barrier is present, so that an emission lifetime of the thin film prepared in Example 4 is shorter than that of the thin film prepared in Example 5.

The emission lifetime of the quantum dot-matrix thin film was reversed in Comparative Examples 1 and 2 and Examples 4 and 5 by changing the structure of the quantum dot-matrix thin film from the quantum dot/matrix structure to the quantum dot/interface layer/matrix structure. That is, in the quantum dot/matrix structure, an emission lifetime of the thin film using the SnSe2 matrix prepared in Comparative Example 2 was shorter than that of the thin film using the SnS2 matrix prepared in Comparative Example 1. However, in the quantum dot/interface layer/matrix structure, an emission lifetime of the thin film using the SnSe2 matrix prepared in Example 4 was shorter than that of the thin film using the SnS2 matrix prepared in Example 5. This is because the electron transport rate from the quantum dot to the matrix was changed in Examples 4 and 5 due to energy level decline by degrees or quantum confinement effect by the interface layer disposed between the quantum dots and the matrix.

As described above, according to the one or more of the above embodiments, physical, chemical, and electrical properties of a quantum dot-matrix thin film may be controlled by adjusting the degree of porosity of the thin film or an interval between quantum dots by controlling an amount of a matrix precursor added to a quantum dot solution.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. A quantum dot-matrix thin film comprising:
a plurality of quantum dots;
an inorganic matrix in which the plurality of quantum dots are imbedded; and
an interface layer disposed between the quantum dots and the inorganic matrix to surround surfaces of the quantum dots.

2. The quantum dot-matrix thin film of claim 1, wherein the quantum dot comprises CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, CdHgZnTe, CdZnSeS, CdZnSeTe, CdZnSTe, CdHgSeS, CdHgSeTe, CdHgSTe, HgZnSeS, HgZnSeTe, HgZnSTe; GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb; SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe; Si, Ge, SiC, SiGe, or any combination of at least two thereof.

3. The quantum dot-matrix thin film of claim 1, wherein the quantum dots have a stack structure.

4. The quantum dot-matrix thin film of claim 1, wherein the inorganic matrix comprises a metal chalcogenide complex.

5. The quantum dot-matrix thin film of claim 4, wherein the inorganic matrix comprises Sn2S6, Sn2Se6, In2Se4, In2Te3, Ga2Se3, CuInSe2, Cu7S4, Hg3Se4, Sb2Te3, or ZnTe.

6. The quantum dot-matrix thin film of claim 1, wherein the interface layer comprises a metal chalcogenide complex.

7. The quantum dot-matrix thin film of claim 6, wherein the interface layer comprises Sn2S6, Sn2Se6, In2Se4, In2Te3, Ga2Se3, CuInSe2, Cu7S4, Hg3Se4, Sb2Te3, or ZnTe.

8. The quantum dot-matrix thin film of claim 1, wherein a material used to form the interface layer and a material used to form the matrix are different from each other.

9. The quantum dot-matrix thin film of claim 1, wherein gaps are formed between the quantum dots.

10. The quantum dot-matrix thin film of claim 1, wherein gaps between the quantum dots are completely filled with the matrix.

11. A method of preparing a quantum dot-matrix thin film, the method comprising:
preparing a quantum dot solution in which quantum dots with inorganic ligands are dispersed;
adding a matrix precursor to the quantum dot solution;
coating the quantum dot solution comprising the matrix precursor on a substrate; and
annealing the substrate coated with the quantum dot solution.

12. The method of claim 11, wherein the quantum dot solution in which the quantum dots with the inorganic ligands are dispersed comprises CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, CdHgZnTe, CdZnSeS, CdZnSeTe, CdZnSTe, CdHgSeS, CdHgSeTe, CdHgSTe, HgZnSeS, HgZnSeTe, HgZnSTe; GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb; SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe; Si, Ge, SiC, SiGe, or any combination of at least two thereof.

13. The method of claim 11, wherein the quantum dots have a stack structure.

14. The method of claim 11, wherein the inorganic ligands comprise a metal chalcogenide complex.

15. The method of claim 14, wherein the inorganic ligands comprise Sn2S6, Sn2Se6, In2Se4, In2Te3, Ga2Se3, CuInSe2, Cu7S4, Hg3Se4, Sb2Te3, or ZnTe.

16. The method of claim 11, wherein the matrix precursor comprises a metal chalcogenide complex.

17. The method of claim 16, wherein the matrix precursor comprises Sn2S6, Sn2Se6, In2Se4, In2Te3, Ga2Se3, CuInSe2, Cu7S4, Hg3Se4, Sb2Te3, or ZnTe.

18. The method of claim 11, wherein the inorganic ligand and the matrix precursor are a same material.

19. The method of claim 11, wherein the inorganic ligand and the matrix precursor are different materials.

20. The method of claim 11, wherein a porosity of the quantum dot-matrix thin film and an interval between the quantum dots are controlled by adjusting an amount of the matrix precursor added to the quantum dot solution.
